(19) United States
(12) Patent Application Publication
(10) Pub. No.: US 2009/0251188 A1
(43) Pub. Date: Oct. 8, 2009

(54) Clock driver and charge pump incluing the same

(75) Inventor: Ju-ha Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/385,286

(22) Filed: Apr. 3, 2009

(30) Foreign Application Priority Data
Apr. 7, 2008 (KR) 10-2008-0032184

(51) Int. Cl. H03K 3/00; G05F 1/10

(52) U.S. Cl. 327/291; 327/536

(57) ABSTRACT

A clock driver capable of minimizing the ripple of an output signal of a charge pump, and the charge pump including the clock driver are disclosed. The clock driver that generates at least one control clock signal for controlling a pumping circuit, the clock driver includes: a first driver generating a first control clock signal by pulling up a first node, in response to a first reference clock signal and pulling down the first node in response to a second reference clock signal; and a second driver generating a second control clock signal by pulling up a second node in response to the second reference clock signal and pulling down the second node in response to the first reference clock signal; wherein the first driver comprises a first hysteresis controller that generates a first output signal having a time delay in response to the rising transition or the falling transition of the second reference clock signal so that the timing for a pulling down operation of the first node is delayed as compared to the timing for a pulling up operation of the second node.

### CROSS-REFERENCE TO RELATED APPLICATIONS

This application claims priority under 35 U.S.C. 119 to Korean Patent Application No. 10-2008-0032184, filed on Apr. 7, 2008, in the Korean Intellectual Property Office (KIPO), the entire contents of which are incorporated herein by reference.

### BACKGROUND

The present invention relates to a clock driver and a charge pump, and more particularly, to a clock driver applied to an image sensor and a charge pump.

Image sensors are semiconductor devices that convert an optical image to an electric signal to display the image corresponding to the electric signal on a display device or store the image in a storage device. Image sensors are mostly used in digital cameras, cellular phones, camcorders, security devices, medical devices and their applications is further increasing.

Image sensors are divided into charge-coupled device (CCD) image sensors and complementary metal-oxide-semiconductor (CMOS) image sensors (CIS). CCD image sensors that use an optimized process have excellent properties in terms of image quality, such as a dark current, conversion efficiency, noise or the like. Meanwhile, CIS have high integration and low power consumption, and operate at high speeds and in a variety of modes. In the image sensor market, CIS that exceed CCD image sensors in terms of image quality have rapidly replaced CCD image sensors.

FIG. 1 is a circuit diagram of a unit pixel 10 of a conventional CIS. A variety of modifications of the unit pixel 10 can be realized. The unit pixel 10 has a plurality of transistors, including a transfer transistor T1, a reset transistor T2, a drive transistor T3, and a select transistor T4. Referring to FIG. 1, the unit pixel 10 includes a photodiode PD that generates photocarriers by receiving light.

The transfer transistor T1 transfers photocarriers accumulated in the photodiode PD to a floating diffusion region FD, in response to a transmission control signal Tx. The reset transistor T2 resets the electrical potential of the floating diffusion region FD to a power supply voltage VDD_pix, in response to a reset signal Rx, thereby discharging photocarriers present in the floating diffusion region FD.

The drive transistor T3 serves as a source-follower buffer amplifier. The select transistor T4 performs an addressing operation. In more detail, the select transistor T4 is switched on, in response to a selection control signal Sx and thus transmits an output signal of the unit pixel 10 via an output port OUT.

To improve the image quality in the conventional CIS, since the conventional CIS needs a voltage higher than a supply voltage, the conventional CIS recently employs a charge pump. For example, to transfer photocarriers accumulated in the photodiode PD to the floating diffusion region FD, a voltage level of the transmission control signal Tx for controlling the transfer transistor T1 is boosted to higher than a supply voltage level. The charge pump can be useful to remove various types of noise that can be included in the power supply voltage VDD_pix. The ripple of an output terminal of the charge pump included in the conventional CIS should be minimized so as to provide a more reliable boosting voltage. It is also beneficial to reduce power consumption of the charge pump that generates the boosting voltage in terms of the characteristics of the conventional CIS that is widely used for portable products.

FIGS. 2A, 2B, and 2C respectively are a circuit diagram of a conventional charge pump 20 and timing diagrams illustrating the waveforms of the operation characteristics thereof. Referring to FIG. 2A, the conventional charge pump 20 includes a pumping circuit 21 for generating a boosting voltage and a clock driver 22 for providing a clock signal to the pumping circuit 21.

The pumping circuit 21 may comprise a main pumping circuit and an auxiliary pumping circuit. The main pumping circuit may comprise precharge transistors MN2 and MN3, pumping capacitors C2 and C3, charge transfer switches MP0 and MP1, and bulk switches MP2 and MP3. The auxiliary pumping circuit may comprise precharge transistors MN0 and MN1 and pumping capacitors C0 and C1.

Meanwhile, an inverter chain driver may be used as the clock driver 22 for driving the pumping circuit 21. Also, a tri-state driver may be used to drive a pumping circuit having a high load current so as to reduce a short-circuit current. The clock driver 22 generates at least one of a plurality of control clock signals clk0 through clk3 by using at least one of a plurality of reference clock signals phi1 and phi2 that are generated by using an external signal. For example, the clock driver 22 generates the four control clock signals clk0 through clk3 by using the two signals phi1 and phi2.

The operation of the conventional charge pump 20 having the above structure will now be described.

When the control clock signals clk0 and clk1 are logic high, the precharge transistors MN2 and MN3 are turned on, and nodes X and Y are precharged to a voltage VDD. Thereafter, when the control clock signals clk2 and clk3 are logic high, the nodes X and Y are increased to a voltage 2*VDD by pumping capacitors C2 and C3. When the control clock signals clk2 and clk3 are logic low, the charge transfer switches MP0 and MP1 are alternatively turned on so that charges of the nodes X and Y are provided as output signals Vcp via output ends. When the bulk switches MP2 and MP3 are alternatively turned on, the conventional charge pump 20 prevents a parasitic transistor (a parasitic BJT) from being turned on. The auxiliary pumping circuit is used to prevent the precharge transistors MN2 and MN3 from being simultaneously turned on.

As described above, the inverter chain driver and the tri-state driver may be used as the clock driver 22. The tri-state driver may be used to generate the control clock signals clk2 and clk3 for driving the main pumping circuit. The tri-state driver comprises a PMOS transistor and an NMOS transistor and uses the signals phi1 and phi2 to control the PMOS and NMOS transistors. In particular, the tri-state driver separately controls the PMOS and NMOS transistors by using the non-overlapping signals phi1 and phi2, thereby preventing the short-circuit current from being generated.

Referring to FIG. 2B illustrating the waveforms of the control clock signals clk0 through clk3 generated by the clock driver 22 shown in FIG. 2A, the clock driver 22 does not have a non-overlapping section between the control clock signals clk2 and clk3 for controlling the main pumping circuit. When the control clock signals clk2 and clk3 are used to control the charge transfer switches MP0 and MP1 of the pumping circuit 21, the charge transfer switches MP0 and MP1 are all turned on, which causes reversion loss. The reversion loss increases the ripple of the output signal Vcp of the conventional charge pump 20 shown in FIG. 2C.

### SUMMARY

One embodiment of the present invention relates to a clock driver capable of reducing or removing a ripple that occurs in the boosting voltage of a charge pump. At least one other embodiment relates to an image sensor including the charge pump.

In one embodiment, there is provided a clock driver that generates at least one control clock signal for controlling a pumping circuit, the clock driver comprising: a first driver generating a first control clock signal by pulling up a first node, in response to a first reference clock signal and pulling down the first node in response to a second reference clock signal; and a second driver generating a second control clock signal by pulling up a second node in response to the second reference clock signal and pulling down the second node in response to the first reference clock signal; wherein the first driver comprises a first hysteresis controller that generates a first output signal having a time delay in response to the rising transition or the falling transition of the second reference clock signal so that the timing for a pulling down operation of the first node is delayed as compared to the timing for a pulling up operation of the second node.

The second driver may comprise a second hysteresis controller that generates a second output signal having a time delay in response to the rising transition or the falling transition of the first reference clock signal so that the timing for a pulling down operation of the second node is delayed as compared to the timing for a pulling up operation of the first node.

Each of the first hysteresis controller and the second hysteresis controller may comprise a hysteresis inverter.

The hysteresis inverter may comprise a first PMOS transistor connected between a power voltage and an output terminal and switched in response to an input signal; first and second NMOS transistors connected between the output terminal and a ground voltage in series and switched in response to the input signal; and a third NMOS transistor connected between a node between the first and second NMOS transistors and the power voltage and switched in response to a voltage of the output terminal.

The hysteresis inverter may comprise first and second PMOS transistors connected between a power voltage and an output terminal and switched in response to an input signal; a third PMOS transistor connected between a node between the first and second PMOS transistors and a ground voltage and switched in response to a voltage of the output terminal; and a first NMOS transistor connected between the output terminal and the ground voltage and switched in response to the input signal.

The first driver may further comprise a first PMOS transistor pulling up the first node based on the first reference clock signal; and a first NMOS transistor pulling down the first node based on the first output signal.

The second driver may further comprise: a second PMOS transistor pulling up the second node based on the second reference clock signal; and a second NMOS transistor pulling down the second node based on the second output signal.

A section of time in which the first NMOS transistor is turned on may be included in a section of time in which the second PMOS transistor is turned on, and a section of time in which the second NMOS transistor is turned on may be included in a section of time in which the first PMOS transistor is turned on, so that a logic low section of the first control clock signal and a logic low section of the second control clock signal do not overlap.

In another embodiment, there is provided a clock driver that generates at least one control clock signal for controlling a pumping circuit comprising a boosting voltage node, the clock driver comprising: a first driver comprising a first pull-up unit for pulling up a first node and a first pull-down unit for pulling down the first node, and generating a first control clock signal by using the first node; and a second driver comprising a second pull-up unit for pulling up a second node and a second pull-down unit for pulling down the second node, and generating a second control clock signal by using the second node; wherein the first driver comprises a first hysteresis controller for delaying the transition timing of the first node to a first logic level so that a first logic level section of the first control clock signal and a first logic level section of the second control clock signal do not overlap.

According to a further embodiment, there is provided a charge pump comprising: a pumping circuit comprising first and second capacitors boosting voltages of first and second boosting voltage nodes; and first and second switches externally providing the voltages of the first and second boosting voltage nodes via an output terminal; and a clock driver comprising a first driver generating a first control clock signal, in response to first and second reference clock signals; and a second driver generating a second control clock signal, in response to the first and second control clock signals, so as to control the boosting voltages of the pumping circuit and first and second switches, wherein at least one of the first and second drivers comprises a hysteresis controller generating an output signal having a time delay, in response to the first reference clock signal or the second reference clock signal, so that sections where the first and second switches are turned on do not overlap.

According to a still further embodiment, there is provided a complementary metal-oxide-semiconductor (CMOS) image sensor (CIS) comprising a pixel array including a charge pump; and a controller configured to control operations of the pixel array wherein the charge pump includes a first driver pulling up a first node based on a first reference clock signal and pulling down the first node based on a second reference clock signal, and generating a first control clock signal; and a second driver pulling up a second node based on the second reference clock signal and pulling down the second node based on the first reference clock signal, and generating a second control clock signal; wherein the first driver comprises a first hysteresis controller generating a first output signal having a time delay, in response to the rising transition or the falling transition of the second reference clock signal, so that the timing for a pulling down operation of the first node is delayed as compared to the timing for a pulling up operation of the second node.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a circuit diagram of a unit pixel of a conventional complementary metal-oxide-semiconductor (CMOS) image sensor (CIS);

FIGS. 2A, 2B, and 2C are respectively a circuit diagram of a conventional charge pump and a timing and a waveform diagram illustrating the waveforms of the operation characteristics thereof;

FIG. 3 is a block diagram of a charge pump according to an embodiment of the present invention;

FIG. 4 is a circuit diagram of the charge pump shown in FIG. 3, according to an embodiment of the present invention;

FIGS. 5A and 5B are respectively a timing and a waveform diagram illustrating the operation characteristics of the charge pump shown in FIG. 4, according to an embodiment of the present invention;

FIGS. 6A and 6B are respectively circuit diagrams of a clock driver shown in FIG. 3 according to embodiments of the present invention; and

FIGS. 7A through 7C are respectively circuit diagrams of a hysteresis controller shown in FIG. 3, according to an embodiment of the present invention.

FIG. 8 is a CIS including a pixel array having a charge pump.

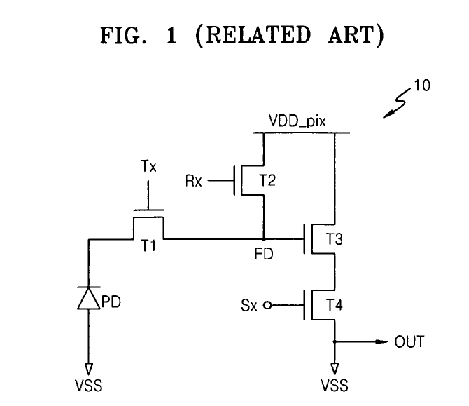

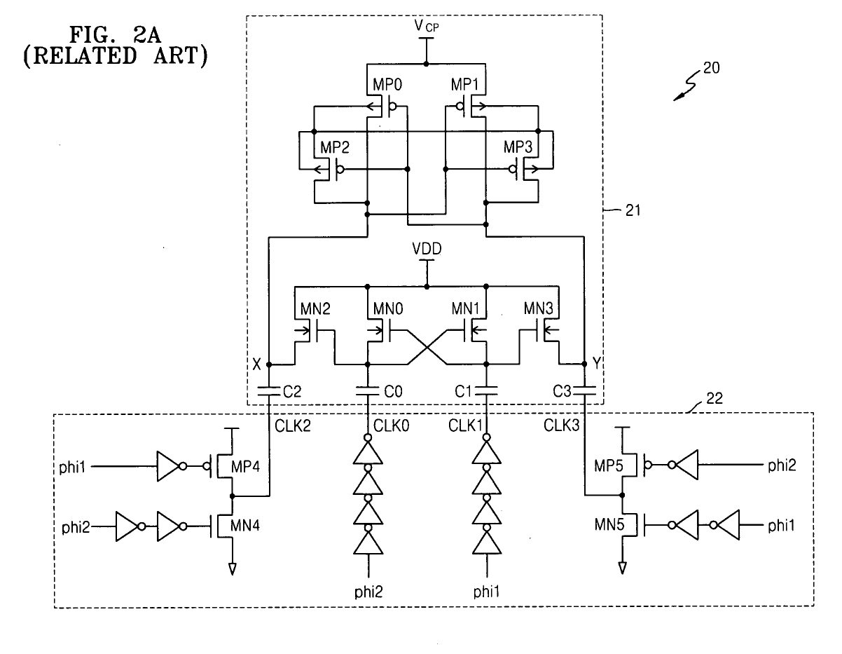

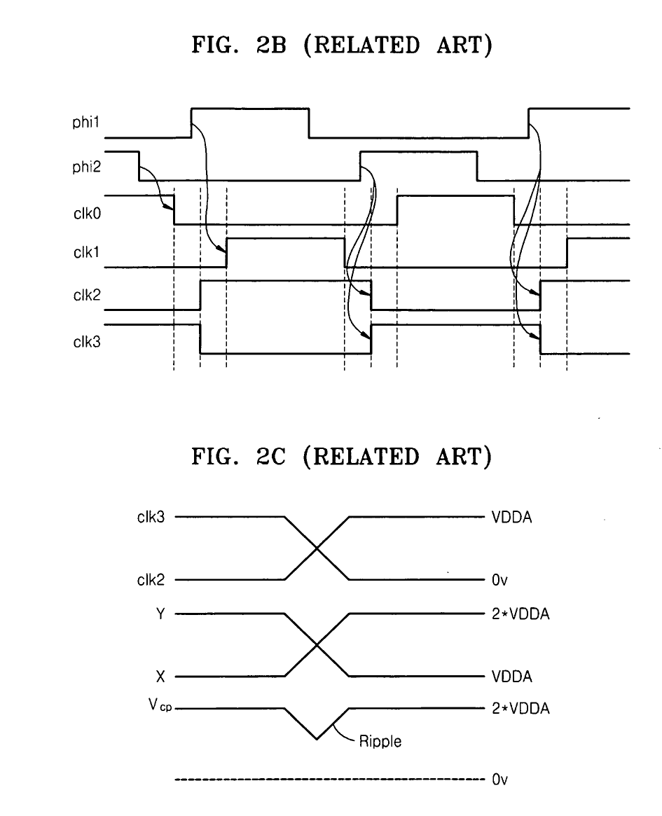

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

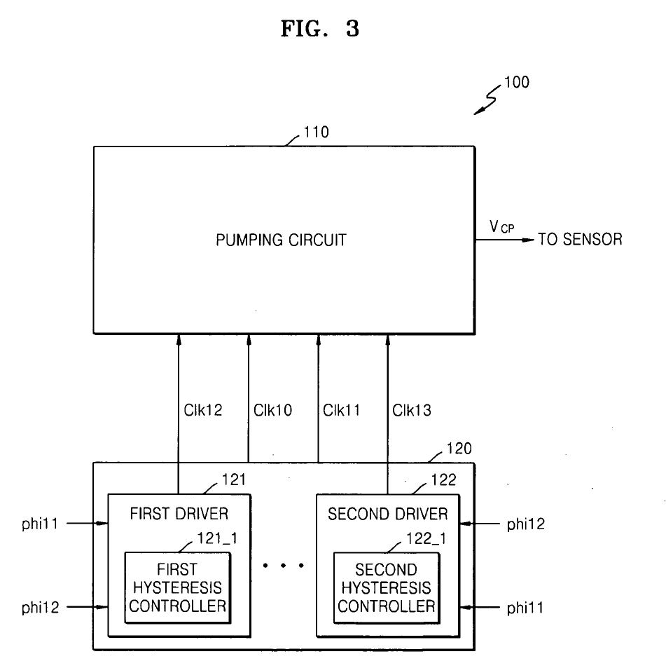

FIG. 3 is a block diagram of a charge pump 100 according to an embodiment of the present invention. Referring to FIG. 3, the charge pump 100 may comprise a pumping circuit 110 and a clock driver 120. The pumping circuit 110 comprises a boosting node (not shown) and externally supplies a boosting voltage as an output signal Vcp. The charge pump 100 may be included in a complementary metal-oxide-semiconductor (CMOS) image sensor (CIS).

The clock driver 120 generates control clock signals clk10 and clk11 and first and second control clock signals clk12 and clk13 for controlling the operation of the pumping circuit 110. Some of the control clock signals may be used to control a main pumping circuit of the pumping circuit 110, and the others may be used to control an auxiliary pumping circuit of the pumping circuit 110. For example, the first and second control clock signals clk12 and clk13 are used to control the main pumping circuit of the pumping circuit 110, and the control clock signals clk10 and clk11 may be used to control the auxiliary pumping circuit of the pumping circuit 110.

The clock driver 120 may be used as an inverter chain driver. A tri-state driver may be used to drive a pumping circuit having a high load current so as to reduce a short-circuit current. The clock driver 120 may comprise a first driver 121 and a second driver 122 that generate the first and second control clock signals clk12 and clk13, respectively, for controlling the main pumping circuit of the pumping circuit 110. The first driver 121 may be the tri-state driver that pulls up or down a first node of the first driver 121, thereby generating the first control clock signal clk12. The second driver 122 may be the tri-state driver that pulls up or down a second node of the second driver 122, thereby generating the second control clock signal clk13. In particular, to prevent the short-circuit current from being generated, the first and second drivers 121 and 122 separately control the pulling-up and pulling-down operations by using first and second reference clock signals phi11 and phi12. The first and second nodes are used to activate switches in the pumping circuit 110. First and second reference clock signals phi11 and phi12 have non-overlapping sections of time with respect to one logic level. First and second drivers are configured to control the first and second nodes such that the first and second nodes have non-overlapping sections of time with respect to one logic level, the logic level activating the switches in the pumping circuit 110, based on first and second reference signals phi11 and phi12. Accordingly, the switches in the pumping circuit 110 connected to the first and second nodes are not activated at the same time.

The operation of the clock driver 120 that generates the control clock signals clk10 and clk11 and the first and second control clock signals clk12 and clk13 will now be described.

The first driver 121 pulls up or down the first node ND11, in response to the first and second non-overlapping reference clock signals phi11 and phi12, and generates the first control clock signal clk12. For example, the first driver 121 pulls up the first node ND11, in response to the first non-overlapping reference clock signal phi11, and pulls down the first node ND11, in response to the second non-overlapping reference clock signal phi12, and generates the first control clock signal clk12. The first node ND11 supplies the first control clock signal clk12 to the pumping circuit 110.

The second driver 122 pulls up or down the second node ND12, in response to the first and second non-overlapping reference clock signals phi11 and phi12, and generates the second control clock signal clk13. For example, the second driver 122 pulls up the second node ND12, in response to the second non-overlapping reference clock signal phi12, pulls down the second node ND12, in response to the first non-overlapping reference clock signal phi11, and generates the second control clock signal clk13. The second node ND12 supplies the second control clock clk13 to the pumping circuit 110.

In the present embodiment, the clock driver 120 may include other drivers for generating the control clock signals clk10 and clk11. When the control clock signals clk10 and clk11 are used to control the auxiliary pumping circuit of the pumping circuit 110, the inverter chain driver 123 for generating the control clock signals clk10 and clk11 may be included in the clock driver 120. Alternatively, the control clock signals clk10 and clk11 may be generated by using the tri-state driver.

The control clock signals clk10 and clk11 generated by the first and second drivers 121 and 122 are used to raise the boosting node of the pumping circuit 110 and control charge transfer switches (not shown) for connecting the boosting node to an output terminal of the pumping circuit 110. For example, the pumping circuit 110 may comprise two charge transfer switches that are controlled by the first control clock signal clk12 and the second control clock signal clk13, respectively. It is necessary to alternatively turn on the two charge transfer switches so as to generate a reliable boosting voltage. In the present embodiment, to turn on the two charge transfer switches, a first logic level section of the first control clock signal clk12 and a first logic level section of the second control clock signal clk13 must not overlap. When the two charge transfer switches are turned on, in response to the logic low first control clock signal clk12 and the logic low second control clock signal clk13, the logic low sections of the first and second control clock signals clk12 and clk13 must not overlap.

To generate the first and second control clock signals clk12 and clk13, at least one of the first driver 121 and the second driver 122 may comprise a hysteresis controller for generating an output signal having a time delay, in response to the rising transition or the falling transition of an input signal. The hysteresis controller receives the first reference clock signal phi11 or the second reference clock signal phi12, and generates the output signal having the time delay, in response to the rising transition or the falling transition of an input reference clock signal. The first driver 121 may comprise a first hysteresis controller 121_1 that receives the second reference clock signal phi12 and generates a first output signal having a time delay, in response to the rising transition or the falling transition of the second reference clock signal phi12. The second driver 122 may comprise a second hysteresis controller 122_1 that receives the first reference clock signal phi11 and generates a second output signal having a time delay, in response to the rising transition or the falling transition of the first reference clock signal phi11.

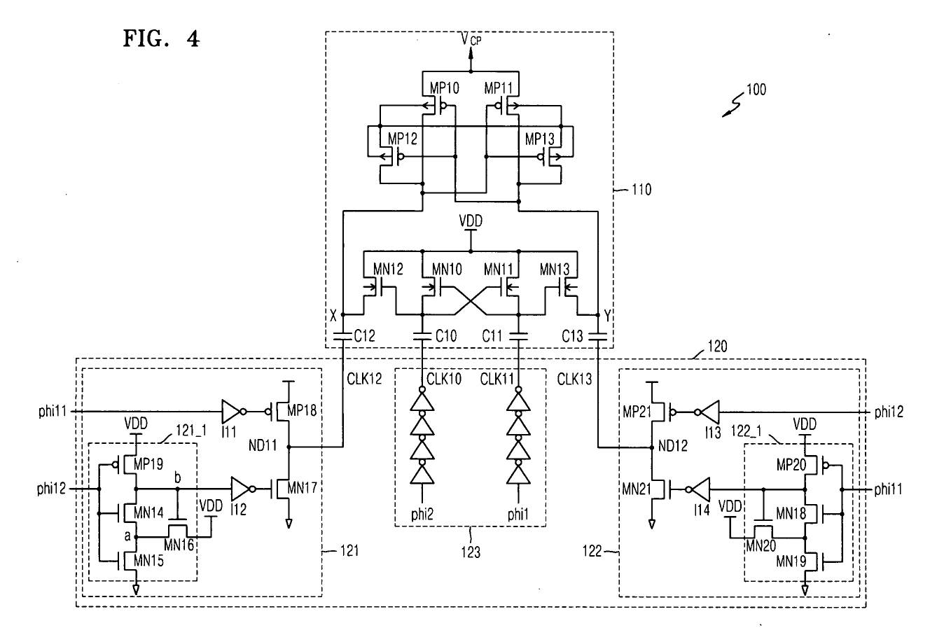

The detailed circuit configuration and operation of the charge pump 100 having the above configuration will now be described with reference to FIG. 4.

FIG. 4 is a circuit diagram of the charge pump 100 shown in FIG. 3 according to an embodiment of the present invention. Referring to FIG. 4, the pumping circuit 110 may comprise the main pumping circuit and the auxiliary pumping circuit. The main pumping circuit may comprise precharge transistors MN12 and MN13, pumping capacitors C12 and C13, charge transfer switches MP10 and MP11, and bulk switches MP12 and MP13. The auxiliary pumping circuit may comprise precharge transistors MN10 and MN11 and pumping capacitors C10 and C11.

The clock driver 120 for driving the pumping circuit 110 generates the control clock signals clk10 and clk11 and the first and second control clock signals clk12 and clk13 by using at least one of the reference clock signals phi11 and phi12 which have non-overlapping sections. For example, the clock driver 120 generates the control clock signals clk10 and clk11 and the first and second control clock signals clk12 and clk13, in response to the reference clock signals phi11 and phi12. In particular, to generate the first and second control clock signals clk12 and clk13 for controlling the main pumping circuit, the clock driver 120 comprises the first and second drivers 121 and 122 that are tri-state drivers. The clock driver 120 for generating the control clock signals clk10 and clk11 may comprise other drivers or tri-state drivers. In the present embodiment, the clock driver 120 comprises inverter chain drivers 123 that generate the control clock signal clk10, in response to the second reference clock signal phi12 and generate the control clock signal clk11, in response to the first reference clock signal phi11.

The first driver 121 may comprise a pull-up unit that pulls up a first node ND11, in response to the first reference clock signal phi11 and a pull-down unit that pulls down the first node ND11, in response to the second reference clock signal phi12. The first driver 121 may further comprise at least one of an inverter I11 and an inverter I12. The pull-up unit may comprise a PMOS transistor MP18 that is switched on/off, in response to the first reference clock signal phi11. The pull-down unit may comprise an NMOS transistor MN17 that is switched on/off, in response to the second reference clock signal phi12. The pulling-up and pulling-down operations of the first node ND11 generate the first control clock signal clk12 having logic high and logic low sections.

The first control clock signal clk12 is supplied to one side of the pumping capacitor C12. A first boosting voltage node X that is precharged to a voltage VDD is boosted to a value corresponding to 2*VDD, in response to the logic high first control clock signal clk12. The charge transfer switch MP11 is turned on, in response to the logic low first control clock signal clk12, and thus, a voltage of a second boosting voltage node Y is externally supplied as the output signal Vcp.

The second driver 122 may comprise a pull-up unit that pulls up a second node ND12, in response to the second reference clock signal phi12 and a pull-down unit that pulls down the second node ND12, in response to the first reference clock signal phi11. The second driver 122 may further comprise at least one of an inverter I13 and an inverter I14. The pull-up unit may comprise a PMOS transistor MP21 that is switched on/off, in response to the second reference clock signal phi12. The pull-down unit may comprise an NMOS transistor MN21 that is switched on/off, in response to the first reference clock signal phi11. The pulling-up and pulling-down operations of the second node ND12 generate the second control clock signal clk13 having logic high and logic low sections.

The second control clock signal clk13 is supplied to one side of the pumping capacitor C13. The second boosting voltage node Y that is precharged to the voltage VDD is boosted to the value corresponding to 2*VDD, in response to the logic high second control clock signal clk13. The charge transfer switch MP10 is turned on, in response to the logic low second control clock signal clk13 and thus a voltage of the first boosting voltage node X is externally supplied as the output signal Vcp.

To remove a reversion loss that may occur when the charge transfer switches MP10 and MP11 are simultaneously turned on, in the present embodiment, first logic level sections (e.g., logic low sections) of the first and second control clock signals clk12 and clk13 do not overlap. For example, when the first node ND11 of the first driver 121 is pulled up and the second node ND12 of the second driver 122 is pulled down, in response to the first reference clock signal phi11, the pulling-down operation of the second node ND12 has a time delay compared to the pulling-up operation of the first node ND11. When the first node ND11 of the first driver 121 is pulled down and the second node ND12 of the second driver 122 is pulled up, in response to the second reference clock signal phi12, the pulling-down operation of the first node ND11 has a time delay compared to the pulling-up operation of the second node ND12. Therefore, the charge transfer switches MP10 and MP11 are alternatively turned on while having a predetermined time delay.

The first and second drivers 121 and 122 each comprise at least one hysteresis controller. In the present embodiment, the first driver 121 comprises a first hysteresis controller 121_1 and the second driver 122 comprises a second hysteresis controller 122_1, the first and second hysteresis controllers 121_1 and 122_1 being hysteresis inverters.

If the first logic level sections of the first and second control clock signals clk12 and clk13 do not overlap, the clock driver 120 may comprise a variety of modifications of the first and second hysteresis controllers 121_1 and 122_1. For example, the first hysteresis controller 121_1 may generate output signals for controlling the PMOS transistor MP18, in response to the first reference clock signal phi11, and for controlling the NMOS transistor MN17, in response to the second reference clock signal phi12. The first hysteresis controller 121_1 may be a hysteresis inverter having a time delay of the falling transition of an output signal, in response to the rising transition of an input signal, or having a time delay of the rising transition of an output signal, in response to the falling transition of an input signal.

Likewise, the second hysteresis controller 122_1 may generate output signals for controlling a PMOS transistor MP2 1, in response to the second reference clock signal phi11, and for controlling an NMOS transistor MN21, in response to the first reference clock signal phi11. The second hysteresis controller 122_1 may be a hysteresis inverter having a time delay of the falling transition of an output signal, in response to the rising transition of an input signal, or having a time delay of the rising transition of an output signal, in response to the falling transition of an input signal.

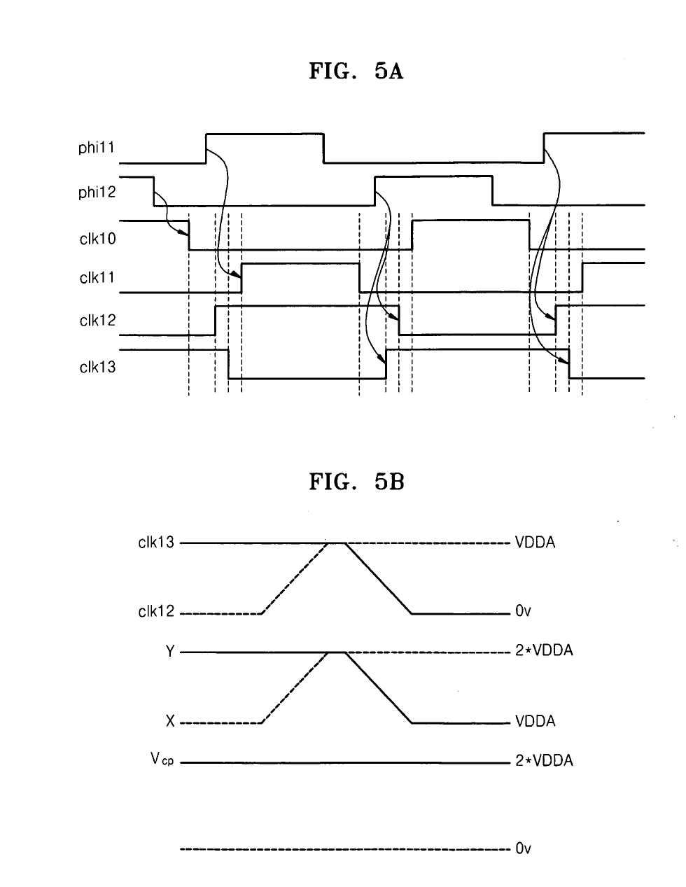

The detailed operation of the first and second drivers 121 and 122 relating to the first and second control clock signals clk1 and clk13 will now be described with reference to FIGS. 5A and 5B. FIGS. 5A and 5B are a timing and a waveform diagram, respectively, illustrating the operation characteristics of the charge pump 100 shown in FIG. 4, according to an embodiment of the present invention.

For descriptive convenience, the first hysteresis controller 121_1 will be described as generating an output signal for controlling the NMOS transistor MN17, in response to the second reference clock signal phi12, and the second hysteresis controller 122_1 will be described as generating an output signal for controlling the NMOS transistor MN21, in response to the first reference clock signal phi11. Also, the first hysteresis controller 121_1 and the second hysteresis controller 122_1 delay the falling transitions of the output signals, in response to the rising transitions of the input signals.

When the second reference clock signal phi12 rises from logic low to logic high, the second node ND12 is pulled up and thus the second control clock signal clk13 rises to a logic high level.

During the logic low section of the second reference clock signal phi12, an output node b of the first hysteresis controller 121_1 is in a logic high state, and an NMOS transistor MN16 is turned on. A node a between NMOS transistors MN14 and MN15 has a voltage value VDD−Vth1 (a threshold value of the NMOS transistor MN16). When the second reference clock signal phi12 rises to logic high (highlight B), the NMOS transistor MN15 is turned on, the voltage of the node a is determined according to a resistance ratio of the NMOS transistors MN15 and MN16. If the second reference clock signal phi12 continues to rise, since a resistance value of the NMOS transistor MN15 is reduced, the voltage of the node a further falls.

If the second reference clock signal phi12 continues to rise and thus the voltage of the second reference clock signal phi12 is higher than that of the node a by Vth2 (a threshold voltage of the NMOS transistor MN14), the NMOS transistor MN14 is turned on. Therefore, a discharge path of the output node b of the first hysteresis controller 121_1 is formed, which reduces the voltage of the output node b. If the output node b is discharged and the voltage of the output node b is lower than the voltage of the node a+Vth1, the NMOS transistor MN16 is turned off. In more detail, the first hysteresis controller 121_1 that is realized as the hysteresis inverter operates in the same manner as a general inverter when the output signal is transitioned from low to high. However, when the output signal is transitioned from high to low, the first hysteresis controller 121_1 has a predetermined time delay.

According to the operation of the first hysteresis controller 121_1, the pulling-down operation of the first node ND11 of the first driver 121 is performed after a predetermined time delay. Therefore, referring to FIG. 5A, the first control clock signal clk12 is transitioned to logic low in the predetermined time delay after the second control clock signal clk13 is transitioned to logic high.

Such an operation is similarly applicable to the second driver 122. In more detail, the second hysteresis controller 122_1 of the second driver 122 has a predetermined time delay, in response to the rising transition of the first reference clock signal phi11 and the output signal of the second hysteresis controller 122_1 is transitioned to logic low. The NMOS transistor MN21 of the second driver 122 is controlled by the output signal of the second hysteresis controller 122_1, so that, referring to FIG. 5A, the second control clock signal clk13 is transitioned to logic low in the predetermined time delay after the first control clock signal clk12 is transitioned to logic high.

The logic low section of the first control clock signal clk12 is included in the logic high section of the second control clock signal clk13, and the logic low section of the second control clock signal clk13 is included in the logic high section of the first control clock signal clk12, as shown in FIG. 5A. Therefore, the charge transfer switches MP10 and MP11 that are switched on, in response to the logic low first and second control clock signals clk12 and clk13 that have a sufficient margin and are alternatively turned on. In more detail, it is possible to prevent the occurrence of the reversion loss caused by the charge transfer switches MP10 and MP11 that are simultaneously turned on, thereby preventing the ripple from occurring in the output signal Vcp of the charge pump 100.

Referring to FIG. 5B that is a waveform illustrating the voltages and the output signal Vcp of the boosting voltage nodes X and Y according to the first and second control clock signals clk12 and clk13, a predetermined time delay occurs when the first control clock signal clk12 rises to a logic high level and the second control clock signal clk13 falls to a logic low level. Therefore, a time delay occurs when the voltage of the boosting voltage node X rises and the voltage of the boosting voltage node Y falls, and the charge transfer switches MP10 and MP11 are not simultaneously turned on, thereby minimizing the ripple of the output signal Vcp of the charge pump 100.

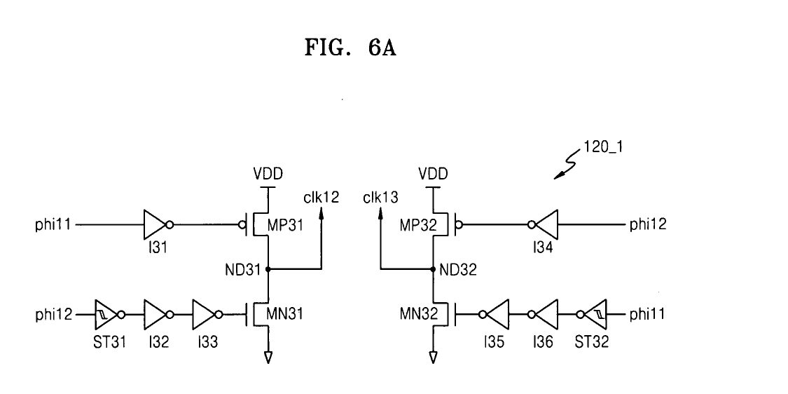

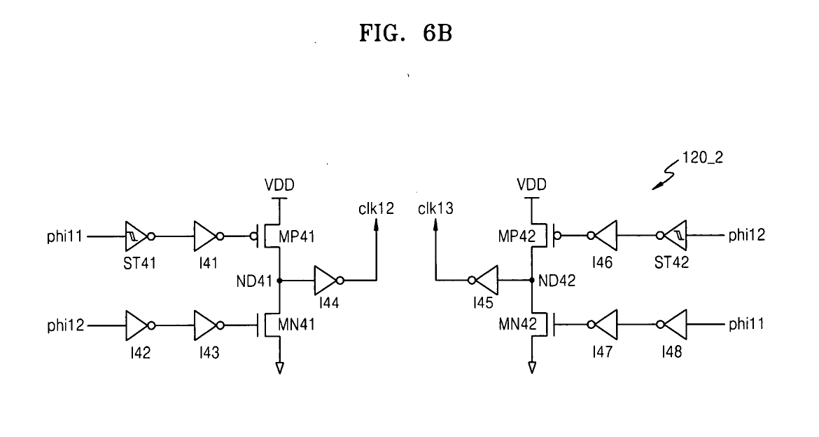

FIGS. 6A and 6B are circuit diagrams of clock drivers 120_1 and 120_2, which are other embodiments of the clock driver 120 shown in FIG. 3. Referring to FIG. 6A, the clock driver 120_1 may comprise a first driver for generating the first control clock signal clk12 and a second driver for generating a second control clock signal clk13.

The first driver may comprise a PMOS transistor MP31 for pulling a first node ND31 up, an NMOS transistor MN31 for pulling the first node ND31 down, and at least one inverter I31 through I33. The first driver may further comprise a first Schmidt trigger ST31 serving as the first hysteresis controller 121_1 shown in FIG. 3. Likewise, the second driver may comprise a PMOS transistor MP32 for pulling a second node ND32 up, an NMOS transistor MN32 for pulling the second node ND32 down, and at least one inverter I34 through I36. The second driver may further comprise a second Schmidt trigger ST32 serving as the second hysteresis controller 122_1 shown in FIG. 3.

The first Schmidt trigger ST31 included in the clock driver 120_1 is used to delay the timing for a pulling-down operation of the first node ND31. In this regard, the first Schmidt trigger ST31 receives the second reference clock signal phi12, and generates an output signal having a time delay, in response to the rising transition or the falling transition of the second reference clock signal phi12. To the contrary, the output signal of the first hysteresis controller is not inverted in FIG. 6A but serves as the NMOS transistor MN31 for pulling the first node ND31 down. To delay the timing for the pulling-down operation of the first node ND31, it may be necessary to delay the timing for the logic high transition of a signal supplied to a gate of the NMOS transistor MN31. Therefore, the first Schmidt trigger ST31 is realized as a circuit that has a predetermined time delay, in response to the falling transition of the second reference clock signal phi12, and generates an output signal having a rising transition.

Similarly, to delay the timing for a pulling-down operation of the second node ND32, it may be necessary to delay the timing for the logic high transition of a signal supplied to a gate of the NMOS transistor MN32. Therefore, the second Schmidt trigger ST32 is realized as a circuit that has a predetermined time delay, in response to the falling transition of the first reference clock signal phi11, and generates an output signal having a rising transition.

Referring to FIG. 6B, the clock driver 120_2 may comprise a first driver for generating a first control clock signal clk12 and a second driver for generating a second control clock signal clk13. Each driver may comprise a pulling-up unit, a pulling-down unit, at least one inverter, and a Schmidt trigger serving as a hysteresis controller.

A clock signal generated by a first node ND41 of the first driver is inverted and is supplied to a pumping circuit as the first control clock signal clk12. A clock signal generated by a second node ND42 of the second driver is inverted and is supplied to a pumping circuit as the second control clock signal clk13. An output of a first Schmidt trigger ST41 of the first driver can control a pulling-up unit MP41 of the first driver, and an output of a second Schmidt trigger ST42 can control a pulling-up unit MP42 of the second driver, so that logic low sections of the first and second control clock signals clk12 and clk13 do not overlap. According to the number of inverters connected to the pulling-up unit MP41 of the first driver, the first Schmidt trigger ST41 can be realized as a circuit for delaying the rising transition of an output signal or a circuit for delaying the falling transition of the output signal. Likewise, according to the number of inverters connected to the pulling-up unit MP42 of the second driver, the second Schmidt trigger ST42 can be realized as a circuit for delaying the rising transition of an output signal or a circuit for delaying the falling transition of the output signal.

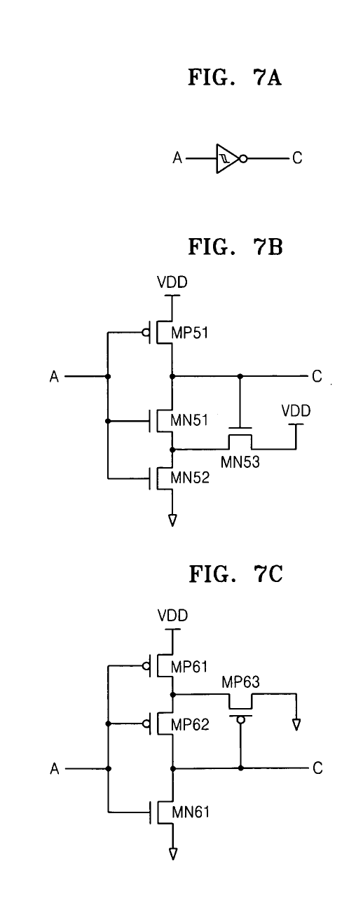

FIGS. 7A through 7C are circuit diagrams of the first hysteresis controller 121_1 or the second hysteresis controller 122_1 shown in FIG. 3 according to an embodiment of the present invention. Referring to FIG. 7A, the hysteresis controller is a hysteresis inverter realized as a Schmidt trigger. In particular, in the present embodiment, the hysteresis inverter responds to any one of the rising transition and the falling transition of an input signal so that an output signal has a predetermined time delay.

Referring to FIG. 7B, the hysteresis controller is a hysteresis inverter that responds to the rising transition of an input signal so that an output signal has a predetermined time delay. The hysteresis inverter may comprise a PMOS transistor MP51 connected between a power voltage VDD and an output terminal C and responding to an input signal A, NMOS transistors MN51 and MN52 connected between the output terminal C and a ground voltage in series and responding to the input signal A, and an NMOS transistor MN53 connected between a node between the NMOS transistors MN51 and MN52 and the power voltage VDD and responding to the voltage of the output terminal C. The NMOS transistor MN53 interferes with a pulling-down operation of the output terminal C, which generates a time delay of an output signal having a falling transition.

Referring to FIG. 7C, the hysteresis controller is a hysteresis inverter that responds to the falling transition of an input signal so that an output signal has a predetermined time delay. The hysteresis inverter may comprise PMOS transistors MP61 and MP62 connected between a power voltage VDD and an output terminal C and responding to an input signal A, a PMOS transistor MP63 connected between a node between the PMOS transistors MP61 and MP62 and a ground voltage in series and responding to the voltage of the output terminal C, and an NMOS transistor MN61 connected between the output terminal C and the ground voltage and responding to the input signal A. The PMOS transistor MP63 interferes with a pulling-down operation of the output terminal C, which generates a time delay of an output signal having a rising transition.

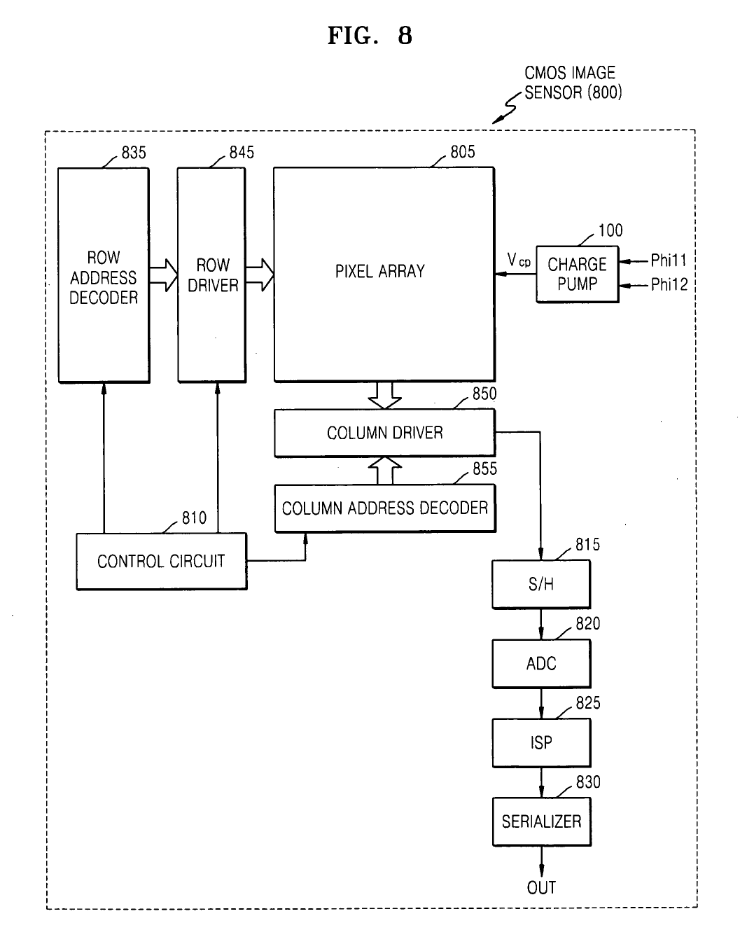

FIG. 8 is a circuit diagram of a CIS including a pixel array having a charge pump. Referring to FIG. 8, CIS 800 includes a pixel array 805 which may include a plurality of unit pixels arranged in a number of columns and rows. Pixels in each row of an array may be activated simultaneously using a row select line and pixels in each column are selectively output according to a column select line. The row select lines are selectively activated by row driver 845 in response to row address decoder 835 and the column select lines are selectively activated by column driver 850 in response to column address decoder 855.

The CIS 800 is operated by the control circuit 810 which controls the row and address decoders 835 and 855 for selecting appropriate row and column lines for pixel readout. The control circuit 810 also includes row and driver circuitry for applying a driving voltage to drive transistors of selected row and column lines. Image data is output from column driver 850 to sample and hold (S/H) circuit 815 and then to analog to digital converter (ADC) 820. Next the image data can be output from ADC 820 to image signal processor (ISP) 825 and then to serializer 830. The image data can then be output to peripheral devices.

CIS 800 also includes the charge pump 100 explained above with reference to FIGS. 3 and 4. Charge pump 100 may be arranged outside pixel array 805, and may provide a voltage Vcp to the pixel array 805. Charge pump 100 may receive reference clock signals phi11 and phi12 from an external source. Charge pump 100 may also receive reference clock signals phi11 and phi12 from control circuit 810.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A clock driver configured to generate at least one control clock signal for controlling a pumping circuit, the clock driver comprising:
a first driver configured to generate a first control clock signal by pulling up a first node in response to a first reference clock signal and pulling down the first node in response to a second reference clock signal; and
a second driver configured to generate a second control clock signal by pulling up a second node in response to the second reference clock signal and pulling down the second node in response to the first reference clock signal;
wherein the first driver comprises a first hysteresis controller configured to generate a first output signal having a time delay in response to at least one of a rising transition or and a falling transition of the second reference clock signal so that timing for a pulling down operation of the first node is delayed with respect to timing for a pulling up operation of the second node.

2. The clock driver of claim 1, wherein the second driver comprises a second hysteresis controller configured to generate a second output signal having a time delay in response to at least one of the rising transition and the falling transition of the first reference clock signal so that timing for a pulling down operation of the second node is delayed with respect to timing for a pulling up operation of the first node.

3. The clock driver of claim 2, wherein each of the first hysteresis controller and the second hysteresis controller comprises a hysteresis inverter.

4. The clock driver of claim 3, wherein the hysteresis inverter comprises:
a first PMOS transistor connected between a power voltage and an output terminal and, the first PMOS transistor configured to switch in response to an input signal;
first and second NMOS transistors connected between the output terminal and a ground voltage in series, the first and second NMOS transistors configured to switch in response to the input signal; and
a third NMOS transistor connected between a node between the first and second NMOS transistors and the power voltage, the third NMOS transistor configured to switch in response to a voltage of the output terminal.

5. The clock driver of claim 3, wherein the hysteresis inverter comprises:
first and second PMOS transistors connected between a power voltage and an output terminal, the first and second PMOS transistors configured to switch in response to an input signal;
a third PMOS transistor connected between a node between the first and second PMOS transistors and a ground voltage, the third PMOS transistor configured to switch in response to a voltage of the output terminal; and
a first NMOS transistor connected between the output terminal and the ground voltage, the first NMOS transistor configured to switch in response to the input signal.

6. The clock driver of claim 2, wherein the first driver further comprises:
a first PMOS transistor pulling up the first node based on the first reference clock signal; and
a first NMOS transistor pulling down the first node based on the first output signal.

7. The clock driver of claim 6, wherein the second driver further comprises:
a second PMOS transistor pulling up the second node based on the second reference clock signal; and
a second NMOS transistor pulling down the second node based on the second output signal.

8. The clock driver of claim 7, wherein the clock driver is configured so that a section of time in which the first NMOS transistor is turned on is included in a section of time in which the second PMOS transistor is turned on, and a section of time in which the second NMOS transistor is turned on is included in a section of time in which the first PMOS transistor is turned on, so that a logic low section of the first control clock signal and a logic low section of the second control clock signal do not overlap.

9. A clock driver that generates at least one control clock signal for controlling a pumping circuit comprising a boosting voltage node, the clock driver comprising:
a first driver comprising a first pull-up unit configured to pull up a first node and a first pull-down unit configured to pull down the first node, the first driver configured to generate a first control clock signal by using the first node; and
a second driver comprising a second pull-up unit configured to pull up a second node and a second pull-down unit configured to pull down the second node, the second driver configured to generate a second control clock signal by using the second node;
wherein the first driver comprises a first hysteresis controller configured to delay a transition timing of the first node to a first logic level so that a first logic level section of the first control clock signal and a first logic level section of the second control clock signal do not overlap.

10. The clock driver of claim 9, wherein the second driver includes a second hysteresis controller configured to delay the transition timing of the second node to the first logic level.

11. The clock driver of claim 10, wherein the first logic level is used to turn on a switch for controlling the connection between an output terminal of the pumping circuit and the boosting voltage node.

12. The clock driver of claim 10, wherein the first pull-up unit is configured to pull up the first node to a second logic level based on a first reference clock signal, and the second pull-down unit is configured to pull down the second node to the first logic level based on an output of the second hysteresis controller, the output of the second hysteresis controller being based on the first reference clock signal,
the second pull-up unit is configured to pull up the second node to a second logic level based on a second reference clock signal, and the first pull-down unit is configured to pull down the first node to the first logic level based on an output of the first hysteresis controller, the output of the first hysteresis controller being based on the second reference clock signal.

13. A charge pump comprising:
a pumping circuit, the pumping circuit comprising
first and second capacitors configured to boost voltages of first and second boosting voltage nodes;
and first and second switches configured to provide the voltages of the first and second boosting voltage nodes externally via an output terminal; and
a clock driver, the clock driver comprising
a first driver configured to generate a first control clock signal, in response to first and second reference clock signals; and
a second driver configured to generate a second control clock signal, in response to the first and second reference clock signals, so as to control the boosting voltages of the pumping circuit and first and second switches,
wherein at least one of the first and second drivers includes a hysteresis controller configured to generate an output signal having a time delay, in response to the first reference clock signal or the second reference clock signal, so that sections of time where the first and second switches are turned on do not overlap.

14. The charge pump of claim 13, wherein the first and second switches are configured to be alternatively turned on, in response to first logic levels of the first and second control clock signals,
wherein at least one of the first and second drivers is configured to generate a control clock signal having a time delay in transitioning to the first logic level based on the output signal of the hysteresis controller.

15. The charge pump of claim 13, wherein the first driver includes
a first pull-up unit configured to pull up a first driver node based on the first reference clock signal;
a first hysteresis controller configured to generate a first output signal having a time delay, in response to a rising transition or a falling transition of the second reference clock signal; and
a first pull-down unit configured to pull down the first driver node based on the first output signal.

16. The charge pump of claim 15, wherein the second driver includes
a second pull-up unit configured to pull up a second driver node based on the second reference clock signal;
a second hysteresis controller configured to generate a second output signal having a time delay, in response to a rising transition or a falling transition of the first reference clock signal; and
a second pull-down unit configured to pull down the second driver node based on the second output signal.

17. The charge pump of claim 16, wherein each of the first hysteresis controller and the second hysteresis controller includes a hysteresis inverter configured to generate an output signal having a time delay, in response to a rising transition or a falling transition of an input signal.

18. The charge pump of claim 16, wherein the clock driver is configured to transition the first control clock signal to logic high by pulling up the first driver node based on the first reference clock signal, and, after the time delay, transition the second control clock signal to logic low by pulling down the second driver node based on the second output signal.

19. The charge pump of claim 18, wherein the clock driver is configured to transition the second control clock signal to logic high by pulling up the second driver node based on the second reference clock signal, and, after the time delay, transition the first control clock signal to logic low by pulling down the first driver node based on the first output signal.

20. A complementary metal-oxide-semiconductor (CMOS) image sensor (CIS) comprising:
a pixel array;
a charge pump configured to provide a voltage to the pixel array; and
a controller configured to control operations of the pixel array,
wherein the charge pump includes,
a first driver configured to pull up a first node based on a first reference clock signal, to pull down the first node based on a second reference clock signal, and to generate a first control clock signal; and
a second driver configured to pull up a second node based on the second reference clock signal, to pull down the second node based on the first reference clock signal, and to generate a second control clock signal;
wherein the first driver includes a first hysteresis controller configured to generate a first output signal having a time delay, in response to a rising transition or a falling transition of the second reference clock signal, so that timing for a pulling down operation of the first node is delayed with respect to timing for a pulling up operation of the second node.

21. The CIS of claim 20, wherein the second driver includes a second hysteresis controller configured to generate a second output signal having a time delay, in response to a rising transition or a falling transition of the first reference clock signal, so that timing for a pulling down operation of the second node is delayed as compared to timing for a pulling up operation of the first node.

22. The CIS of claim 21, wherein each of the first hysteresis controller and the second hysteresis controller includes a hysteresis inverter.
